(19) United States
(12) Patent Application Publication
(10) Pub. No.: US 2014/0326883 A1
(43) Pub. Date: Nov. 6, 2014

(54) NANOWIRE THERMOELECTRIC INFRARED DETECTOR

(71) Applicants: Reza Abdolvand, Winter Park, FL (US); Mohammad Jafar Modarres-Zadeh, Tulsa, OK (US)

(72) Inventors: Reza Abdolvand, Winter Park, FL (US); Mohammad Jafar Modarres-Zadeh, Tulsa, OK (US)

(73) Assignee: THE BOARD OF REGENTS FOR OKLAHOMA STATE UNIVERSITY, STILLWATER, OK (US)

(21) Appl. No.: 14/365,308

(22) PCT Filed: Jun. 11, 2012
(86) PCT No.: PCT/US2012/041902

§ 371 Date: Jun. 13, 2014

Related U.S. Application Data
(60) Provisional application No. 61/422,397, filed on Dec. 13, 2010.

(51) Int. Cl. G01J 5/16; G01J 5/04

(52) U.S. Cl. CPC G01J 5/16; G01J 5/046; G01J 2005/126
USPC 250/338.1; 29/592.1

(57) ABSTRACT

A thermoelectric infrared detector. The detector has an absorption platform comprising a material that increases in temperature in response to incident infrared radiation and the platform covering substantially an entire area of the detector. The detector includes a thermocouple substantially suspended from contact with a substrate by at least one arm connected to the substrate.

### CROSS REFERENCE TO RELATED APPLICATION

This application claims the benefit of U.S. Provisional Application No. 61/422,397 filed Dec. 13, 2010, and PCT Application No. PCT/US2011/064744, filed Dec. 13, 2011, herein incorporated by reference in its entirety for all purposes.

### FIELD OF THE INVENTION

This disclosure is related to infrared sensing in general and, more particularly, to thermoelectric infrared detectors.

### BACKGROUND OF THE INVENTION

At this point in time, thermal infrared (IR) imaging arrays can't compete with the cryogenically-cooled photon detector arrays in responsivity and detectivity. However, the cryogenic-coolers required for long wavelength photon detectors impose disadvantages such as increased size/cost, and reduced life time. Photon detectors are also sensitive to a limited spectrum of IR radiation. Therefore, there has always been a strong motivation for development of high-performance thermal IR detectors that operate at room temperature. Today, the manufacturing cost of a thermal IR imaging array is still considerably high and the performance is limited by the structure of the detector and more specifically by the heat transfer between the isolated sensitive area and the surroundings.

What is needed is a system and method that addresses the above and related issues.

### SUMMARY OF THE INVENTION

The invention of the present disclosure as described and claimed herein, in one aspect thereof, comprises a thermoelectric infrared detector. The detector has an absorption platform comprising a material that increases in temperature in response to incident infrared radiation and the platform covering substantially an entire area of the detector. The detector includes a thermocouple substantially suspended from contact with a substrate by at least one arm connected to the substrate.

In some embodiments, the thermocouple comprises a thermoelectric connection embedded in the at least one arm. The absorption platform may connect directly to the at least one arm forming the thermocouple. The absorption platform may also comprise at least one layer dielectric layer with at least two adjacent metal layers. The at least two adjacent layers may be on opposite sides of the dielectric layer and may comprise nichrome. The detector may include an adhesion layer underlying the dielectric layer and the two metal layers.

In some embodiments, the at least one arm comprises Parylene. The at least one arm may be tethered to the substrate by at least one tether, which may comprise Parylene.

The invention of the present embodiment as disclosed and claimed herein, in another aspect thereof, comprises an infrared detector. The detector includes a plurality of support arms proceeding from a substrate and containing a plurality of thermoelectric connections therein. The detector includes an infrared absorber platform in thermal connection with the plurality of arms and heating the arms in response to absorbing infrared radiation. The thermoelectric connections form a thermocouple with the absorber, the absorber acting as a hot junction and the substrate acting as a cold junction, the thermocouple providing a voltage signal on the thermoelectric connections in proportion to the temperature difference between the hot and cold junctions.

In some embodiments, the plurality of support arms comprise Parylene. The detector may further comprise at least one tether tethering at least one of the plurality of support arms to the substrate at a location other than where such support arm joins the substrate.

In some embodiments, the absorber platform covers substantially an entire area of the detector. The absorber platform may comprise a silicon nitride layer with a first nichrome layer on a first side of the silicon nitride layer and a second nichrome layer on a second side of the silicon nitride layer. An adhesion layer may be provided on a lower side of the absorber platform. The detector may include a silicon nitride post interposing the infrared absorber and the plurality of arms.

The invention of the present disclosure as described and claimed herein, in another aspect thereof, comprises a method including providing an infrared absorber, providing a plurality of Parylene support arms supporting the absorber away from the substrate, and attaching a thermally conductive connection from the substrate to the infrared absorber to detect heating of the absorber relative to the substrate. The method may include forming the infrared absorber from a dielectric layer covered on two sides by metal layers. The infrared absorber may be configured to cover substantially all of the support arms.

### BRIEF DESCRIPTION OF THE DRAWINGS

FIG. 1 is a perspective view of one embodiment of an infrared (IR) detection cell according to aspects of the present disclosure.

FIG. 2 is a comparison of responsivity (left) and detectivity (right) of a TE IR detector for different TE materials at room temperature.

FIG. 3 is a comparison of the responsivity of the element for different materials configurations.

FIG. 4 is a comparison of the detectivity of the element for different materials configurations.

FIG. 5 is a comparison of the time constant of the element for different materials configurations.

FIG. 6 is a cutaway view of a process flow for the fabrication of an IR detector according to aspects of the present disclosure.

FIG. 7 is another perspective view of an IR detector, on cell according to aspects of the present disclosure.

FIG. 8 is another cutaway view of a process flow for the fabrication of an IR detector according to aspects of the present disclosure.

FIG. 9 is a perspective view of another embodiment of an IR detector according to aspects of the present disclosure.

FIG. 10 is a perspective view of the IR detector of FIG. 9 with the absorber removed.

### DETAILED DESCRIPTION OF THE PREFERRED EMBODIMENTS

Infrared (IR) radiation detectors can be categorized into two classes: photon and thermal detectors. The principle of operation in a photon detector is to measure the change in the electrical properties (electronic energy distribution) of a material as a result of interaction between absorbed photons and the electrons. Since thermally generated charge carries will introduce noise in photon detectors, cryogenic cooling is necessary to attain sensitivity to IR wavelength larger than 2-3 μm. In addition, photon detectors will only show sensitivity to a narrow range of IR wavelength based on the engineered band-gap of the material used as the sensing element.

Thermal detectors, on the other hand, operate based on measuring the change in the electrical properties of a material as a result of the temperature change subsequent to the absorption of the IR radiation. With the presumption that the absorption coefficient of the sensing material in a thermal detector is fairly constant for a wide range of IR wavelength, the detector can be used for a wide spectrum and does not require cooling. This is a significant advantage of thermal detectors over their counterparts and has inspired extensive research in universities and industry for decades. Thermal IR detectors are mostly classified in three categories based on the detection mechanism as introduced below.

In resistive detectors, the resistance of a sensing element is changing as the temperature of the element varies corresponding to the amount of absorbed thermal energy. The change in resistance is converted to the change in voltage by passing a constant bias current through the resistance. In these devices the responsivity (defined as the output signal divided by the input radiation power) is proportional to the thermal resistance from the sensing area to the heat sink and the temperature coefficient of resistance.

Pyroelectric detectors operate based on the pyroelectric effect, which is the spontaneous electric polarization as a result of change in the temperature in a pyroelectric film and is measured as a voltage developed on a pair of electrodes covering the two surfaces of the film. Pyroelectric detectors do not respond to constant IR radiation (when there is no temperature change) and radiation modulation (chopping) is necessary for their operation in imaging applications. Similar to resistive detectors, the responsivity in pyroelectric detectors is also proportional to the thermal resistance of the thermally isolated heat collector.

In a thermoelectric detector, the temperature variation in the IR absorption area is turned into a corresponding voltage using a thermopile. The thermoelectric effect is a self-generating transduction mechanism and therefore alleviates the need for a bias signal. As expected, the responsivity in a thermoelectric detector is proportional to the thermal resistance and the difference between the Seebeck coefficients of the two thermoelectric materials used in the thermopile. The rather small Seebeck coefficient of conventional thermoelectric materials can be partially augmented by using a series combination of a number of thermoelectric junctions.

Limits of Detectivity in Thermal Detectors

Noise in thermal detectors originates from both thermal and electrical sources. Random change in the temperature of the sensing element arising from the statistical nature of the heat exchange between the sensor and the surrounding environment is known as temperature fluctuation noise. This noise can fundamentally limit the detectivity of a thermal IR detector. Detectivity in this context is defined as square root of sensing area divided by the noise equivalent power: (D*=A_{IR}^{1/2}/NEP) with the units of cmHz^{1/2} W⁻¹. With this definition, the temperature fluctuation noise-limited detectivity in a thermal detector is defined as:

$${D}_{TF}^{*} = {( \frac{{A}_{b}^{2} {A}_{IR} {R}_{th}}{4 {k}_{B} {T}^{2}} )}^{1 / 2} \qquad ( 1 )$$

where A_{b} is the absorption coefficient, A_{IR} is the absorption area, Rₜₕ is the thermal resistance of the support (assuming that conduction is the dominant heat exchange mechanism), k_{B} is the Boltzmann's constant and T is the system temperature. Interestingly, it is observed that the thermal resistance (Rₜₕ) has the same overall effect on the detectivity as it has on responsivity (both improve as the Rₜₕ increases). Therefore, the thermal detector (of any kind) exhibit an ultimate detectivity if we assume thermal conduction is removed altogether and the only remaining heat exchange mechanism is radiation. This detectivity is called background fluctuation noise-limited detectivity and is formulated as below:

$${D}_{BF}^{*} = {[ \frac{{A}_{b}}{8 {k}_{B} σ ( {T}_{D}^{S} + {T}_{B}^{S} )} ]}^{1 / 2} \qquad ( 2 )$$

where σ is the Stefan-Boltzmann constant and the T_{B} and T_{D} are the background and the detector temperature respectively. The detectivity of all thermal devices will always be smaller than this limit. It should be noted that even after greatly suppressing the thermal conduction in a thermal sensing device achieving the background noise-limited detectivity is not guaranteed. This is because other electrical sources of noise such as Johnson noise and 1/f noise (for devices biased at a DC signal) will also affect the detectivity of the IR detector.

Effect of Reducing the Absorption Area

From the size and cost standpoint, scaling down the IR detector pixel size may be desirable. However, from equation 1 it is observed that the temperature fluctuation noise-limited detectivity of a detector is proportional to the square root of A_{IR}. But, the effect of sensing area on the performance is not accurately understood unless the concept of noise equivalent temperature difference (NETD) is introduced. The NETD which is more relevant to the performance of IR imaging arrays is defined as the change in the temperature of an object in the view of the imager which results in a signal to noise ratio of equal one. So the lower this number is the better the quality of the image produced by the imager would be. A general equation defining the temperature fluctuation noise-limited NETD in thermal IR arrays is as follows:

$$N E T {D}_{TF} = \frac{( 4 {F}^{2} + 1 ) {T ( {K}_{B} B / {R}_{th} )}^{1 / 2}}{{A}_{b} {τ}_{0} {A}_{IR} ( Δ P / Δ T )} \qquad ( 3 )$$

where F is the f/no. of the lens, B is the measurement bandwidth, τ₀ is the transmittance of the optics, and (ΔP/ΔT) is the change in power per unit area of the object at temperature T measured within a specific spectral band. The important observation here is that even though NETD is inversely proportional to the IR absorption area (A_{IR}) reducing the pixel size will not necessarily result in smaller signal to noise ratio. The effect of smaller area can be compensated by reducing the f/no. and therefore a lower size/cost IR camera is achieved while preserving the performance.

Employing thermoelectric sensing methods in an IR detector offers many benefits. For example, as mentioned earlier, thermoelectric sensors do not require a bias signal (as opposed to all resistive and some pyroelectric detectors). Therefore, the output signal is free of 1/f noise and Johnson noise is the only source of electrical noise in the sensor. This means that by suppressing the heat conduction of the support structure and carefully designing the resistance of the thermopile (to reduce Johnson noise), the thermoelectric detector is the most likely of all thermal detectors to reach background-noise-limited detectivity discussed above with a very reasonable manufacturing cost.

Resistive detectors and some pyroelectric detectors need a temperature stabilizer in order to operate in a wide range of temperature (e.g. 0-50° C.). The temperature coefficient of resistance in a resistive detector and the dielectric constant in a pyroelectric detector are strong functions of the absolute temperature (the material in use is set at transition temperature to increase responsivity). Therefore, the temperature of the sensing array has to be controlled. This is not the case for a thermoelectric detector in which the reference temperature is always automatically set by the bulk of the substrate which is acting as a heat sink.

Another significant advantage of a thermoelectric detector is the capability to measure constant radiation which eliminates the need for a mechanical chopper.

Collectively, all the above characteristics suggest that a thermoelectric detector is a superior choice for implementation of low-cost, compact and durable IR imaging devices.

Micromachined Thermoelectric IR Arrays

Micromachined thermoelectric IR detectors have received considerably less attention compared to their pyroelectric and resistive counterparts; and majority of current commercially-available IR imaging arrays are based on the two latter types. Considering the aforementioned advantages of the thermoelectric sensing elements, this mediocre popularity among IR imaging producers may be associated with the lower reported responsivity of the thermoelectric IR detectors (˜108 cmHz1/2W−1).

In these devices, the thermoelectric junction is made of doped polysilicon, metals, or a combination of both. In the majority of published work on thermoelectric detectors, the thermally isolated area is either entirely suspended on a thin dielectric (usually silicon nitride) membrane or suspension arms are made of silicon nitride (or silicon oxide). The thermal conductivity of silicon nitride is rather large and therefore the thermal conduction through the suspension arms is increased. Even the thermal conductivity of silicon dioxide is not low enough to provide excellent isolation. Therefore, the overall thermal isolation of the sensing element and consequently responsivity of the detector is usually compromised.

The performance of thermoelectric detectors can be improved by incorporating more efficient thermoelectric material such as Bi—Te compounds. The detectivity for such devices is reported in the range of a 109 cmHz1/2W−1, which is comparable to the detectivity of pyroelectric and resistive devices. However, the present disclosure shows that the detectivity can be improved by an order of magnitude beyond this value with carefully optimizing the detector structure and the thermopile dimension/configuration. This can be achieved without the need for the rare/exotic materials that are typically incompatible with conventional microelectronics fabrication. Thermoelectric IR pixels integrated with low-noise electronic amplifiers can lead to mass-production of low-cost and compact thermoelectric imaging arrays that are suitable for low-power applications (such as space exploration missions).

Advanced Thermoelectric Materials.

The thermal to electrical energy conversion efficiency of a TE device operating between Tₕ and T_{c} is determined by the average figure of merit (ZT) of the TE material. ZT is a measure of performance of the TE material and depends on combination of three properties of a material: thermal conductivity (x), electrical conductivity (o) and Seebeck coefficient (S):

$$Z T = \frac{{S}^{2} σ}{κ} T \qquad ( 4 )$$

where T is the average temperature in Kelvin.

One of these techniques is the use of nanostructures that improve or maintain thermoelectric power factor (S²σ) through quantum size effects or interface energy filtering, while their thermal conductivity is reduced through the scattering of phonons at superlattice interfaces. Some examples of these groups are bulk PbTe based materials, BiTe/SbTe superlattices (SL), PbTe/PbSeTe quantum dot superlattices (QDSL), and more recently BiSbTe nanocomposite structure and Si TE nanowires.

TE Properties of Silicon Nanowires

Silicon as a bulk material has a large thermal conductivity (κ>100 W/mK), hence it is a poor TE material (ZT<0.02 at 300K). When it is alloyed with Ge in Si_{0.8}Ge_{0.2} form, the thermal conductivity reduces to about 5 W/mK and consequently the figure of merit at high temperature is increased (ZT˜1 at 1300K). However, SiGe is still a poor TE material at room temperature (ZT˜0.2 at 300K). Recently, a group of researchers investigated the TE properties of rough Si nanowires (NW). Silicon NWs demonstrated a significantly larger figure of merit even at room temperature (ZT˜1 at 300K). The main reason for this enhancement is believed to be the large reduction in the thermal conductivity (κ˜1.6 W/mK) and enhancement of Seebeck coefficient (S˜240 μV/K) while maintaining a good electrical conductivity (σ˜280 S/cm).

Device Structure

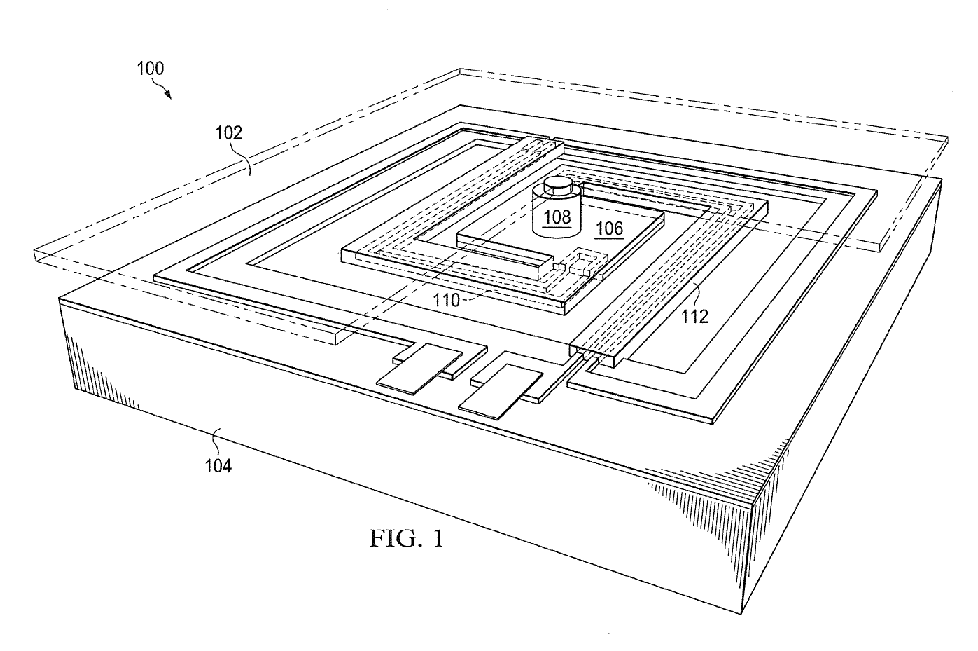

Referring now to FIG. 1. a perspective view of an IR detection cell 100 according to aspects of the present disclosure is shown. A radiation absorption platform 102 in this design is raised above the surface of substrate 104 in an attempt to maximize the fill-factor. A portion of the absorption platform 102 is cut out in FIG. 1 to make the details of the device 100 more visible to the reader. In such a design, the incident radiation will mostly be absorbed by the sensing area 102, and electrical connections are covered by the absorber.

The absorber 102 is made of material with high thermal conductivity, low density, and high IR absorption coefficient (such as silicon nitride) and the thickness of the film is minimized to reduce the heat capacitance. The absorber 102 is connected to a relatively small membrane of silicon nitride 106 via a post 108 in the middle. In the present embodiment, a thermoelectric junction is created by placing polysilicon nanowires 110 in thermal contact with this bottom membrane 106 (e.g., it lays on top of the membrane). The polysilicon nanowires 110 are embedded inside two turning arms 112 that suspend the entire structure and create excellent thermal isolation between the absorber 102 (hot junction) and the bulk of the substrate 104 (cold junction heat sink). In one embodiment, the suspension arms 112 are made of made of Parylene or polyimide.

The thermoelectric nanowires 110 directly convert the temperature difference originated by the absorption of IR radiation to a voltage signal. In order to efficiently suppress parasitic heat transfer, the nanowire thermocouples 110 are embedded in membranes made of organic material with an ultra-low thermal conductivity, such as Parylene or polyimide, to support the suspended mass of the sensing area 102. Some embodiments of the present disclosure are expected to reach the fundamental limit of detectivity (the background fluctuation noise limit at room temperature) currently unattainable by thermal IR detectors.

It should be understood that the number of thermoelectric junctions placed in series is only for illustration, and more or fewer may be present in various embodiments. The arms 112 are turned around the suspended membrane 106 to create a longer path. This lowers thermal conductance while keeping a small total footprint. Thus the pixel size can be reduced resulting in smaller overall package and lower cost. Responsivity and detectivity of a pixel in an IR imaging array may depend on fill factor. In embodiments of the present design, the IR absorber 102 covers the whole area of the array, and almost all the incident IR radiation will be absorbed and converted to image data.

The sensitivity and detectivity of a TE detector increases with the thermal resistance between the hot and cold junctions. The Si NW TE legs 112 of the present disclosure provide a very high thermal resistance for two reasons: first, reduced thermal conductivity of the material while maintaining the TE power factor; and second, very large length to area ratio. The two effects result in a significantly large thermal resistance (>1010 K/W) which is hardly attainable by conventional TE structures.

To take the most advantage of the large thermal resistance of the nanowire TE, one has to carefully design the device structure. The two dominant heat exchange mechanism in such a device are (1) convection through the air and (2) conduction through the support that is embedding the NWs. To eliminate the convection, usually the detector is packaged in a vacuum seal. The heat conduction through the support 112 adds to the total thermal conduction across the two ends of TE junction and results in a smaller responsivity.

Silicon nitride (SiN) has previously been used to form the support 112. However, silicon nitride has a large thermal conductivity (˜30 W/mK) compared to that of Si nanowires (κ˜1.6 W/mK) and therefore, the overall thermal isolation of the structure is deteriorated. For this reason, a support 112 made from Parylene may be used. Parylene demonstrates an extremely small thermal conductivity (κ˜0.08 W/mK) comparable to that of air (κ˜0.03 W/mK). A Parylene membrane significantly reduces the heat conduction path parallel to the Si nanowires 110 resulting in enhanced responsivity and detectivity of the detector 100.

Thermal detectors usually suffer from slower response time compared with the typical photon detectors. The thermal time response of a TE detector can be characterized by:

τ=CₜₕRₜₕ (5)

where Cₜₕ is the effective thermal capacity that depends on the mass and the specific heat, and Rₜₕ is the effective thermal resistance of the device from the IR absorber to the cold end of the sensor. The thermal capacity of the device is attributed to the IR absorber 102, the TE legs 112, and all other supporting materials that are thermally connected to the device. In a device with large fill factor, the large IR absorber dominates the thermal capacity. A smaller IR absorber can enhance the time response; however there is a trade-off between sensitivity of the sensor and the response time. In the present device, both the absorber 102 area/mass and the material of choice are optimized to target a balanced performance. To improve the IR absorption a thin Au-black layer can be coated by low pressure evaporation. The small mass density of Au-black is ˜20 times smaller than Au. This will significantly enhance the time response while maintaining the sensitivity. Au-black layer demonstrates a fairly large IR absorption coefficient (>90%) in the range of λ˜5-17 μm wavelength.

Silicon offers numerous cost and manufacturing advantages when used as a device component but typically is not an obvious choice when it comes to TE properties (ZT of silicon is low as discussed before). However, in the following we will explain why nanowire silicon is an excellent choice for IR sensing applications. In addition to the thermal management of the device, the ultimate responsivity and detectivity of the TE IR detector is dependent on the properties of the TE material. A good TE material is generally one that exhibits the highest figure of merit ZT, where ZT is a measure of thermoelectric performance. However, for a TE IR detector, ZT is not the appropriate parameter for the choice of the TE material. The thermoelectric parameters must enhance the most important sensor performance parameters namely responsivity and detectivity. The responsivity R and the thermal fluctuation noise-limited detectivity D_{TF} of a simple TE detector (no power modulation) is determined by the following two relations:

$$\begin{matrix}R = N S {R}_{th} {A}_{b} {A}_{r} & ( 6 ) \\ {D}_{TF} = \sqrt{\frac{Signal}{Thermal noise}} = \frac{R \sqrt{{A}_{IR}}}{\sqrt{4 {k}_{B} {TR}_{el}}} & ( 7 )\end{matrix}$$

where N is the number of TE pairs, S is the difference of the Seebeck coefficients of the two legs (i.e. Sₚ−Sₙ), Rₜₕ is the thermal resistance between the hot and cold junctions, A_{b} is the IR absorption absorptivity, Aᵣ is the fill factor, A_{IR} is the area of the IR absorber, Rₑₗ is the total electrical resistance of the TE legs, T is the absolute temperature, and k_{B} is the Boltzmann constant. If we ignore non-ideal heat conductions and assume that the thermal conduction between the hot and cold junctions is only due to the TE pairs we have:

$${R}_{th} = \frac{1}{2 N} \frac{{l}_{TE}}{κ {A}_{TE}} \qquad ( 8 )$$

And for the electrical resistance of the TE leg we have:

$${R}_{el} = 2 N \frac{{l}_{TE}}{σ {A}_{TE}} \qquad ( 9 )$$

where l_{TE} and A_{TE} are the length and the cross section area of each TE leg, respectively. Substituting Rₜₕ and Rₑₗ in (6) and (7), we have:

$$\begin{matrix}R = \frac{{A}_{b} {A}_{r}}{2} \frac{{l}_{TE}}{{A}_{TE}} \frac{S}{κ} -> R ∝ \frac{S}{κ} & ( 10 ) \\ {D}_{TF} = \frac{{A}_{b} {A}_{r} \sqrt{{A}_{c}}}{2 \sqrt{4 {Nk}_{B} T}} \sqrt{\frac{{l}_{TE}}{{A}_{TE}}} \sqrt{\frac{{S}^{2} σ}{{κ}^{2}}} -> {D}_{TF} ∝ \frac{1}{T} \sqrt{\frac{ZT}{κ}} & ( 11 )\end{matrix}$$

Based on equ. (10) in order to achieve a high responsivity, a TE material with large Seebeck to thermal conductivity ratio is desired. This does not necessarily mean a large ZT as generally expected for a superior TE material. For example, if we compare Bi₂Te₃, PbTe, and Si_{0.8}Ge_{0.2} as three conventional TE materials, at room temperature Bi₂Te₃ has the highest ZT˜1, and SiGe has the smallest ZT˜0.2 (n or p at doping concentration˜10¹⁹ cm⁻³). However, SiGe at this doping level has a very large Seebeck coefficient (S˜650 μV/K) as compared with Bi₂Te₃ (S˜210 μV/K) and PbTe (S˜100 μV/K). This results in a significantly larger S/κ ratios for SiGe. Therefore, a TE IR detector made with SiGe will have a larger responsivity compared to a similar device made from Bi₂Te₃ or PbTe. For the case of detectivity, ZT/κ is the selection rule. This factor, however, is larger for Bi₂Te₃.

To demonstrate the performance of a typical TE IR detector versus different TE materials, we calculated the responsivity and detectivity of a TE IR detector with similar device structure when it is made with BiTe, PbTe, or SiGe TE legs. We assumed a device with total absorption area of 30 μm×30 μm, SiN suspended layer under the TE sensors with thickness and width of 100 nm and 350 nm, respectively. We assumed cylindrical TE legs each with a length of 150 mm and calculated the responsivity and detectivity versus the diameter of the TE wires. We further assume similar TE properties both for n and p type materials as listed in Table 1 shows the comparison of the responsivity and detectivity of this device made with different TE materials. Similar values of detectivity for BiTe and responsivity for Si based TE IR detector have already been reported.

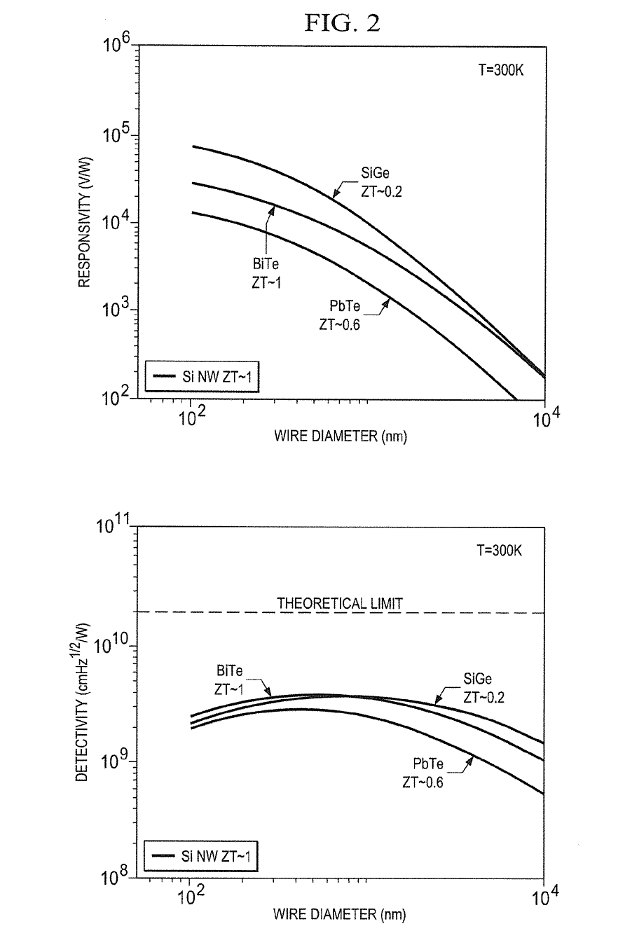

As shown in FIG. 2, it is interesting to notice that SiGe, despite its small value of ZT, shows a significantly higher responsivity while its associated detectivity is on the same order as those of BiTe and PbTe based IR detectors. In a TE IR detector, the responsivity is a function of the S/κ ratio and the detectivity is a function ZT/κ ratio. We have also shown similar parameters calculated for a device made with Si nanowire TEs (50 nm NW diameter) for comparison. As we discussed in Section 3.9, Si NW has demonstrated enhance TE properties.

Thermal Analysis

In the design of the TE IR detector, in addition to the choice of materials used for each element of the device, we have to consider several important geometrical features to optimize the detector performance. Some if these features are: the number of TE couples N, their length l and diameter d, support membrane thickness tₘ, IR absorber area A_{IR} and thickness t_{IR}. The polysilicon nanowires are fabricated by oxidizing larger polysilicon beams. After oxidation the oxide layer will be removed and the NW is embedded in Parylene. The theoretical model calculations used here are very much similar to that of Vashaee et al. used for modeling of InP thin film coolers. The Si NW parameters are extracted from the experimental data reported by Hochbaum et al. To demonstrate the performance of NW polysilicon TE IR detector we have calculated and compared the responsivity, detectivity, and response time of a design with total absorption area of 30 μm×30 μm, cylindrical TE legs each with a length of 150 μm.

Table 1 lists the parameters used in our calculations.

TABLE 1
Device parameters and material properties

| # of TE pairs in each beam | N = 3 | | SiN layer thickness | 0.5 | μm |
|---|---|---|---|---|---|
| Total area of the sensor, A_{IR} | 30 μm × 30 μm | | IR absorber thickness, t_{IR} | 0.5 | μm |
| Membrane thickness, tₘ | 0.5 | μm | IR absorber supporter area | 7 μm × 7 μm | |
| Au-black specific heat | 1260 | j/kgK | Si specific heat | 712 | j/kgK |
| Au-black mass density | 965 | kg/m³ | Si mass density | 2330 | kg/m³ |
| SiN thermal conductivity | 30 | W/mK | Parylene thermal conductivity | 0.08 | W/mK |
| Si NW Seebeck coefficient | 240 | μV/K | Si bulk Seebeck coefficient | 663 | μV/K |
| Si NW thermal conductivity | 1.6 | W/mK | Si bulk thermal conductivity | 100 | W/mK |
| Si NW electrical conductivity | 280 | S/cm | Si bulk electrical conductivity | 106 | S/cm |
| PbTe Seebeck coefficient | 100 | μV/K | BiTe Seebeck coefficient | 210 | μV/K |
| PbTe thermal conductivity | 2.7 | W/mK | BiTe thermal conductivity | 1.4 | W/mK |
| PbTe electrical conductivity | 6000 | S/cm | BiTe electrical conductivity | 1000 | S/cm |

Responsivity

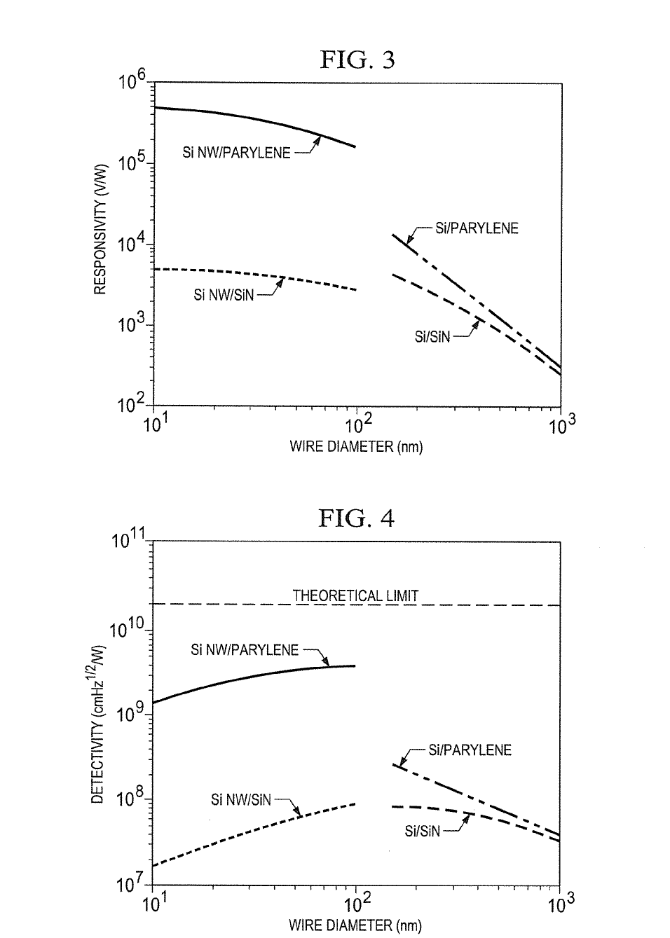

Once the equivalent thermal resistance across the hot and cold junctions is determined, the responsivity of the detector can be estimated using equ. (6). One way to improve the TE responsivity is to increase the number of nanowires N. However, this will reduce the overall thermal resistance. Therefore, it is important to optimize the number of nanowires versus other parameters of the device. We determined that for our device three pairs of NWs in each beam gives the highest responsivity. FIG. 3 shows the calculated responsivity versus the TE wire diameter. The lines in the figure are disconnected in the 100-150 nm range to separate two regimes of NW and bulk conduction. When the wire diameter is small (<100 nm), the thermal conductivity of Si is assumed to be in NW regime estimated by 1.6 W/mK. In larger wire diameters (>150 nm), the thermal conductivity is taken as that of bulk Silicon (˜100 W/mK). Other parameters are listed in

In Table 1 it is seen that smaller wire diameter can result in larger responsivity as expected. We also considered two different membranes one made from SiN and one from Parylene with similar geometries for comparison. It is interesting to notice that for the case of NW, the device with Parylene membrane results in a responsivity that is two orders of magnitude larger. This is mainly due to the extremely small thermal conductivity of Parylene (˜0.08 W/mK) that would significantly reduce the parasitic heat conduction to the substrate.

Detectivity

There exists a trade-off between the responsivity and detectivity in terms of optimizing the geometry of the TE wires. Increasing the ratio of the total length to the cross section area of the wire lNW/ANW would increase the thermal resistance of the wire. That would enhance the responsivity of the detector; however, the detectivity decreases due to the increase in electrical resistance resulted from larger Johnson noise.

In order to achieve reasonably enhanced values for both parameters, we design the device structure to achieve a detectivity close to the theoretical limit of 1.98×1010 cmHz1/2/W, while maximizing the responsivity of the device. FIG. 4 shows the calculated detectivity versus the wire diameter. It is seen that the Si NW with Parylene membrane results in a detectivity that is approaching the theoretical limit. For a Si NW with 50 nm diameter, this is equal to ˜1010 cmHz1/2/W that is significantly larger than values achievable by today's uncooled IR detectors.

Response Time

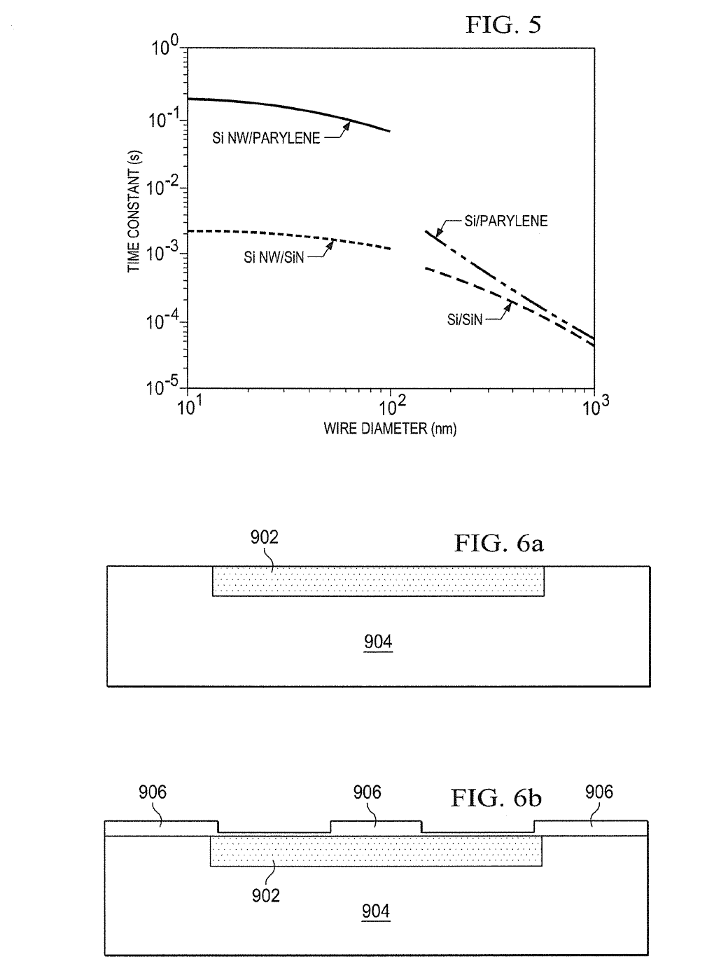

There is also a fundamental trade-off between the responsivity of the TE IR detector and its thermal time response as they depend in opposite ways on the thermal resistance of the TE wire. In order to enhance the time response of the proposed device while maintaining its high responsivity, we intend to reduce the heat capacity of the device instead (see equ. 5). For this purpose, we propose to use thin (˜0.5 um) and low density (˜1 g/cm³) black gold deposited on a thin silicon nitride layer for the IR absorber to reduce the thermal mass, hence decreasing the response time. This will reduce the time response of a 50 nm Si NW IR detector below 100 ms, which is appropriate for video frame rate applications. See FIG. 5.

Finite Element Analysis

In order to confirm the results of our models we solved the heat transfer equation for the three dimensional structure using finite element method in COMSOL. Heat conduction in all segments and radiation from and to all the surfaces are considered in this analysis. It was observed that for a very small amount of IR radiation (˜1 nW), there exists a detectable temperature difference across the TE legs (˜0.9 C). The TE pair in the sensor is capable of producing measurable voltage for temperature differences in the range of one thousandth of a degree. This simulation agrees with our calculations that show two orders of magnitude enhancement in responsivity (˜10⁶ V/W) compared to that of conventional uncooled IR detectors (i.e. <10⁴ V/W)

Fabrication Process Flow

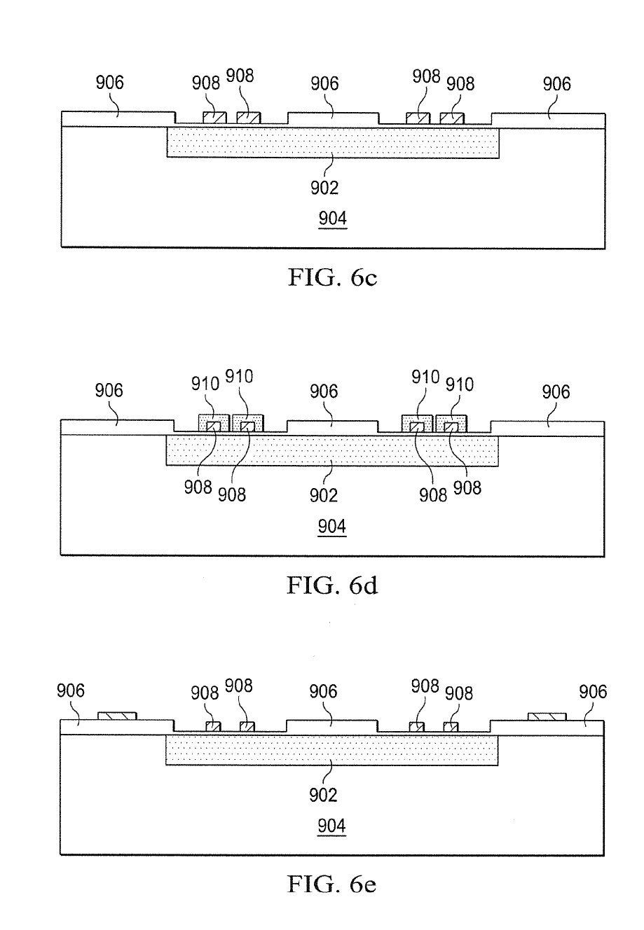

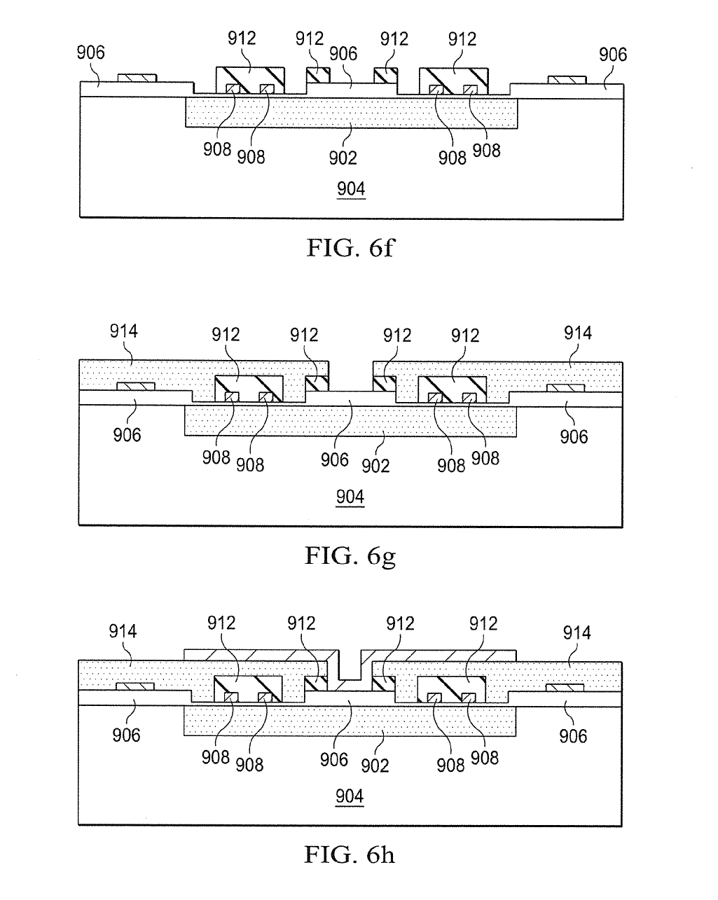

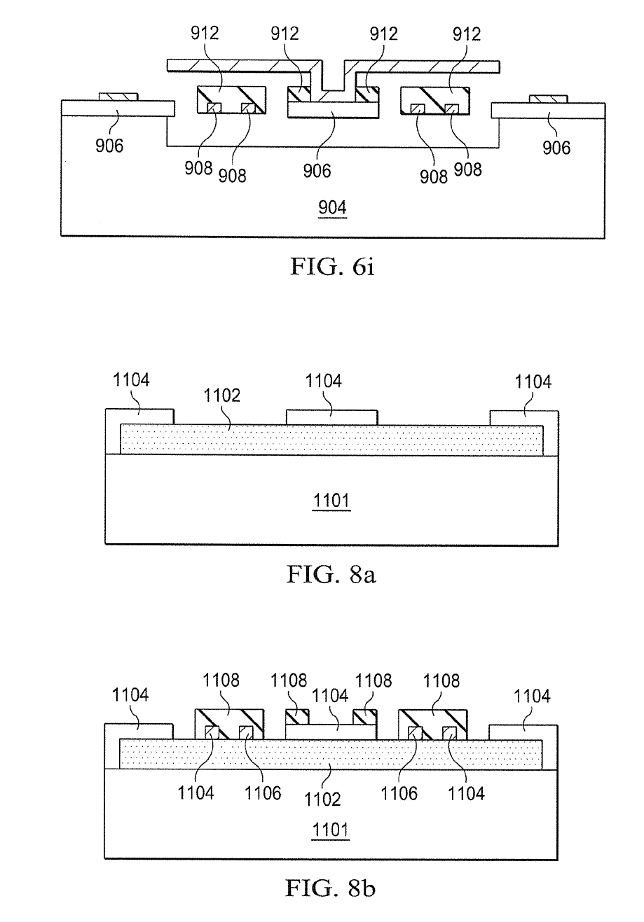

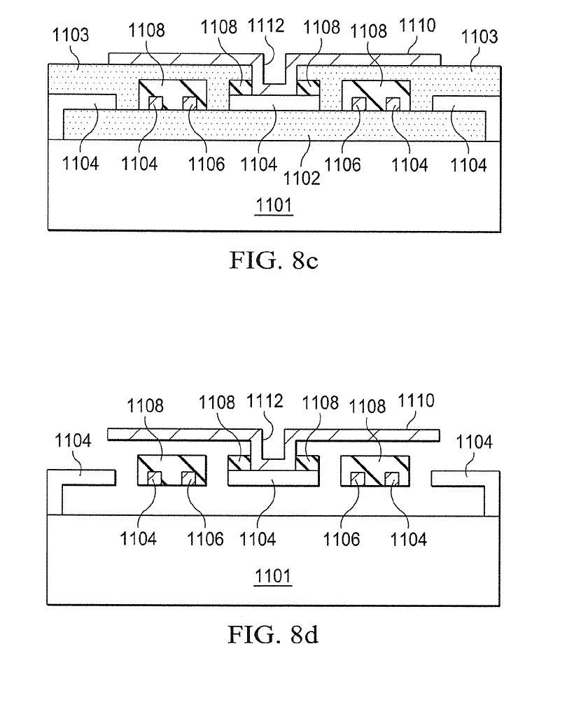

Referring now to FIGS. 8a-8e, one embodiment of a step-by-step process flow for fabrication of a thermoelectric detector is shown. These figures represent the cross section of a detector unit (such as that of FIG. 1). The process begins at FIG. 6a by forming an oxide-filled cavity 902 in a silicon wafer 904. This can be done in several ways. For example, a thin layer of silicon nitride on the surface of the wafer can be deposited and patterned (oxidation barrier). Then the wafer is oxidized in an oxidation furnace and finally the wafer is polished back to remove the nitride layer. The detector will be fabricated on top of this oxide island in order to facilitate the release of the structure at the end.

Next in FIG. 6b, a layer of low-stress silicon nitride 906 is deposited on the surface of the wafer in a low pressure chemical wafer deposition (LPCVD) furnace and patterned as needed. It is notable that the nitride layer is not completely removed on the patterned area and rather a very thin layer of nitride is left. This layer should be thick enough to withstand a short BOE dip in on the subsequent steps. The nitride pattern in the middle of the oxide island comprises the suspended bottom membrane 106 of FIG. 1.

A thin layer of polysilicon is deposited, selectively ion implanted and patterned to form the thermoelectric traces 908 as show in FIG. 8c. Since the polysilicon wires are planned to be very narrow (nanoscale), a size reduction technique (by oxidation of the polysilicon) is utilized to scale down the size of the patterned polysilicon as seen better in FIG. 6d. In this oxidation process, polysilicon is oxidized from the surface, resulting in the formation of SiO₂ as a cladding 910 around the wires, also seen in FIG. 6d. During this process, polysilicon wire remains in the core and becomes thinner as the oxidation continues. By controlling the temperature and oxidation time, we can attain the desired nanowire diameter. An alternative method to make polysilicon nanowire would be to use e-beam lithography. However, that is not a batch fabrication technique and may not be directly transferable to large-scale production lines.

Next, the oxide 910 from the oxidized polysilicon wires 908 is removed in BOE as shown in FIG. 6e. At this point the thermoelectric junction is formed on the silicon nitride membrane 106 by selective metal evaporation (e.g. lift-off) at the tip of the wires (not shown in this cross section).

It should be noted that in some embodiments, the wires 908 (denoted 110 in the finished product shown in FIG. 1) may not be silicon based. In some embodiments, Bismuth and Ni—Cr are chosen as the metal traces 908 since they exhibit a combined Seebeck coefficient of about 100 μV/° C. which is a relatively large value for metals

A thin layer of Parylene 912 is deposited and patterned in oxygen plasma to form the thermally-insulating enclosure for the nanowires 910 in FIG. 8f. The Parylene structure also supports the suspended structure as shown in FIG. 1. Parylene is highly hydrophobic and resistant to humidity. It is not soluble in most organic solvents (such as many resist removers) and does not react with most acidic/basic solutions (such as HF and KOH).

In FIG. 6g, a sacrificial layer 914 for deposition of the IR absorber is formed. Depending on the material chosen for the absorber this mold can be made of a range of material (e.g. resist). One option is to use a thin (<1 m) sputtered silicon nitride layer. Since sputtering is a low-temperature deposition technique most sacrificial material are suitable. After patterning the silicon nitride absorber 102 as shown in FIG. 6h, the surface of absorber may be coated with high IR absorptivity material (gold-black) for improved performance. The last step is to release the entire structure in solvents and BOE consecutively as shown in FIG. 6i. The absorber mold made of resist will be removed in solvents and the oxide sacrificial layer in BOE to completely suspend the sensing platform. The etch rate of Parylene in BOE is negligible and it can withstand long BOE bath if required.

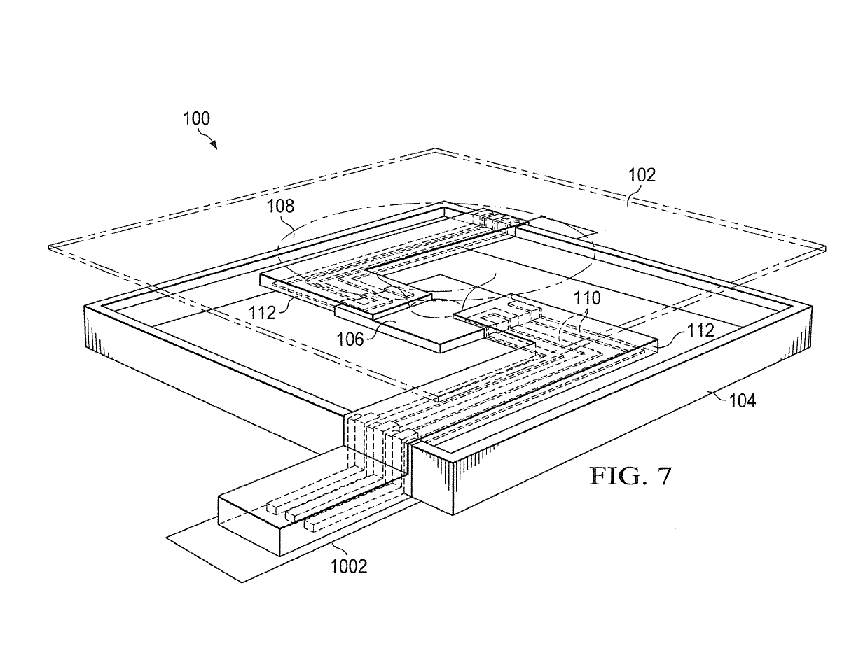

Referring now to FIG. 7, another illustration of one embodiment of an IR detection cell is shown. Here it may be seen how the absorber 102 is connected to the membrane 106 via post area 108. The electrical traces 110 are embedded in the Parylene support arms 112 which support the membrane 106 (serving as a thermocouple) and absorber 102. In the present embodiment, the traces or thermoelectric wires 110 run from the substrate 104, serving as a cold junction, to the suspended silicon nitride membrane 106, serving as a hot junction, then back to the substrate 104 again. Various connections 1002 may be provided for connecting the detection cell 100 to logic or other circuitry. It is understood that in use, a plurality of cells 100 may be used in an array. As described, the fill factor of the cell 100 promotes it use in detector arrays. Additionally, the processes described herein for production of the cell 100 are readily adaptable to batch production and the entire process may be post CMOS compliant.

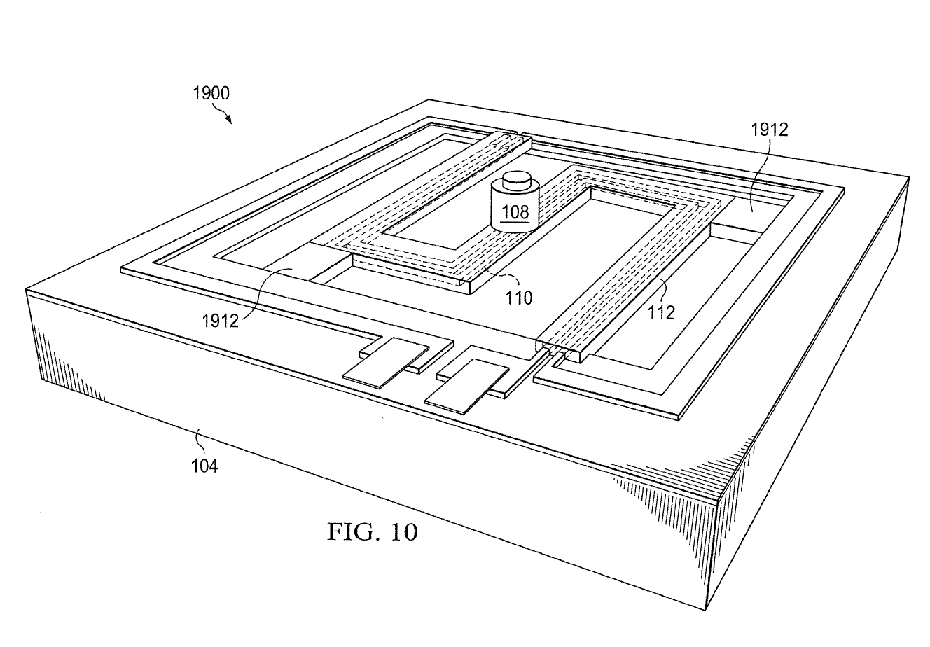

Referring now to FIGS. 8a-8d, another process flow for constructing devices according to the present disclosure is shown. As illustrated in FIGS. 10a-10d, prototype devices with various absorber sizes and different number of thermocouple junctions have been fabricated using a 7-step surface-micromachining. This process utilizes two sacrificial layers 1102, 1103 as explained below. This process begins with the deposition of a sacrificial PECVD SiO2 layer 1102, which is patterned to serve as the platform for the suspended heat-collector 1110 (the absorber 102 of FIG. 1). Silicon nitride 1104 is then deposited and patterned by dry etching to serve as an insulation layer for the electrical connections on top of both the substrate and the heat-collection post in the middle (FIG. 8 (a)).

The thermoelectric junctions are formed by sputtering/patterning two different traces 1104, 1106 and then the Parylene film 1108 is deposited in a Parylene-coating chamber at room temperature and is consequently patterned in O2 plasma (FIG. 8 (b)). The absorber 1110 is then formed and patterned to create access to the bottom silicon nitride post 1112 (106 of FIG. 1) as shown in FIG. 8(c). The heat-collector (Cu) is then deposited/patterned and is anchored to the post through the patterned hole in resist. At last, both sacrificial layers are removed to completely release the structure (FIG. 8 (d)).

Below is a description of one way in which the steps above were implemented to produce a detector according to the present disclosure.

The fabrication process begins with a single side polished silicon 1101. The wafer is cleaned prior to any deposition to make sure that it is free of any contamination. Any contamination may cause some unknown effects and undesired film formation in the later steps.

There are different choices of sacrificial layers 1102, 1103. Polymers such as photoresist can be used as a sacrificial layer but they are not suitable for high temperature processes since they might burn. Some polymers can tolerate high temperature but ash technique which is used for removal is harmful to Parylene films which itself is a polymer. Other sacrificial layer like silicon dioxide, silicon nitride, polysilicon, etc. can also be used but except silicon dioxide, other materials either hard to remove or their etchant attacks other material on the wafer. Silicon dioxide can be etched in Hydrofluoric solutions (HF). The HF solution slightly attacks Parylene and silicon but this is not the concern here, the important is that it strongly attacks oxide and gives a good selectivity.

After cleaning, sacrificial oxide is deposited. This can be done either in oxidation furnace or PECVD. PECVD oxide is preferable because this film will be removed later on and has higher etch rate in the etchant comparing to the thermal oxide. Also the oxide deposition rate in PECVD (2 um per hour) is much higher than the growth rate in furnace (more than 8 hours for 2 um).

Undoped silicon wafers can be very expensive and doped ones may short the thermoelectric traces to each other and cause malfunction. To avoid this, a thin layer of an insulator material should be deposited. This layer will not be removed and should not be etched in HF solution. Silicon nitride is the choice of option since it can tolerate high temperature, it is slightly attacked in HF, and it can be deposited with the common IC fabrication tools. Another requirement is that the insulator film should have high thermal conductivity to dissipate the transferred heat from the hot element quickly. Silicon nitride has high thermal conductivity and can rapidly conduct any local heat to the other cold areas.

Silicon nitride was chosen for the present build because it could be deposited using PECVD and has high deposition rate. Upon different parameters in the process, the deposited film may have different etch rates. A recipe was developed to produce films with low stress and low etch rate in BOE and is shown in Table 2.

TABLE 2
Nitride deposition recipe

| | | | | | RF | Process |
|---|---|---|---|---|---|---|
| Temperature | SiH₄ + He | NH₃ | He | N₂ | power | pressure |
| (C.) | (sccm) | (sccm) | (sccm) | (sccm) | (watts) | (mTorr) |
| 300 | 1600 | 5 | 1200 | 450 | 80 | 750 |

After nitride deposition, the film should be patterned to form a SiN membrane 1104 on the center of the sacrificial oxide which will act as the hot junction.

Thermoelectric wires 1104, 1106 are required to generate voltage due to the temperature difference on their ends. Among metals, Bismuth's Seebeck coefficient is relatively large. It was decided to use sputtering technique instead of thermal evaporation. In general, sputtering provides better sidewall coverage.

One of the thermoelectric wires, was made from polysilicon since it has higher ZT. Polysilicon is deposited in a LPCVD furnace at which should be followed by annealing for dopants activation at. Since this film is deposited at high temperature, lift-off is not an option because photoresists are polymers and they cannot withstand temperatures higher than 150° C. unless they are cured. If they are cured, they can no longer be removed in Acetone and another method which is called ash technique should be used for removal. So, the film has to be dry etched in ICP. Another consideration is that a recipe should be used for etching polysilicon that does not etch the underneath layer especially since polysilicon is thin and timing the process is difficult. This polysilicon layer is deposited over silicon nitride and silicon dioxide. Thus, a great selectivity is required. In addition, the etching should be isotropic and a great undercut can be attained and hence, the width of the wire can be controlled. Thus, a recipe was developed based on SF6 plasma for etching the polysilicon layer. In the developed recipe the etch-rates of photoresist, silicon dioxide and polysilicon are 85, 43, and >1000 nm/min respectively.

The only problem that was observed with this technique was that the widths of the wires on the sidewalls were much smaller than other places. In other words, the polysilicon etch-rate on the sidewalls is more than the flat surfaces. This non-uniform etching can be taken care of by changing the wire patterns. Thus, in the design step, wires with larger widths on the side walls are drawn.

Parylene is deposited at room temperatures with a Specialty Coating Systems (SCS) tool. The thickness of the result film depends on the amount of the loaded dimer. Parylene-C with different thicknesses were deposited and patterned. Oxygen based plasma is used to etch the Parylene film in ICP. Since photoresist is a polymer as well as Parylene, it cannot be used as a mask. Even if the thickness of the photoresist mask is chosen much thicker than the thickness of the Parylene film, the etched film result will not have sharp and good sidewalls. A hard mask such as silicon dioxide should be used.

The next step in the fabrication process is absorber 1110 deposition. Since the absorber 1110 may be deposited at high temperature, higher than 300° C., Parylene C is not proper because its melting point is 290° C. Parylene N has almost the same characteristic but it has higher melting point, 480° C. Thus, Parylene N films were deposited by acquiring the necessary dimer and applying some modifications inside the tool.

The sacrificial layer 1103 for absorber 1110 was deposited next. Again, for the sake of simplicity, photoresist was used as the sacrificial layer and copper was used as the absorber material. As it was shown in FIG. 8(c), the sacrificial layer 1103 should be etched in order to gain access to the silicon nitride membrane 1104. As a result, the absorber 1110 can be anchored to silicon nitride membrane through a post 1112. Using photoresist, the sacrificial layer 1103, can be easily patterned for the post 1112 and then the absorber 1110 can be deposited at room temperature. If the temperature of the substrate 1101 rises during the absorber deposition, the post might crack, and after releasing, the absorber would be detached.

Different recipes for Cu sputtering were tried to avoid heat damage to the sacrificial photoresist. Among different parameters in the process, the applied power to the target had the greatest effect. By reducing this power, a uniform film with no heat damage to the sacrificial layer was deposited. This deposited film should be etched to form the absorber 1110. This can be done by using a photoresist as a mask and wet etching the Cu film.

After patterning the absorber 1110, the absorber and the device can be released by submerging the device in acetone to remove the sacrificial photoresist followed by BOE dip for removing the sacrificial oxide. Devices may be built with different numbers of Parylene arms 112 (FIG. 1) but it was found that devices with four arms may fare better in the releasing process. However, some success was achieved by releasing the devices in HF vapor and then baking them to remove any residue.

To avoid baking, devices may be released from the backside of the wafer. There are two known ways to etch a wafer from the backside. One way is Bosch process or DRIE (deep reactive ion etching) which results to steep side walls. The other way is anisotropically wet etching with KOH or TMAH. For this process, larger holes on the backside are required. Both of the techniques were pursued to release the devices.

After completing a process on the wafer, the front side was protected with 2 um of PECVD oxide for wet etching the backside. After an hour of etching in TMAH, it was observed that the front side has been attacked and the polysilicon wires were wiped off the front surface. Apparently, PECVD oxide is not a good protecting mask. Another protective layer, Protek, was added to the front side and etching lasted for 6 hours.

When the Parylene film goes under heat cycles, an internal stress will be induced. The author believes that the film eases the internal stress at the annealing temperature and the induced stress is the result of thermal coefficient mismatch between the Parylene film and the underneath layer. It has been shown that at first, the deposited Parylene has tensile stress, but after a heat cycle, the stress will become compressive. Specifically, Parylene N goes under phase change at and which these phase changes will reduce the internal stress. To further lessen this stress, in any heat cycle, the sample should be slowly cooled down. This induced stress is the result of thermal mismatch between the Parylene film and the underneath layer.

Since the generation of stress inside the Parylene film is inevitable, two small supports (of Parylene, for example) may be added to the Parylene film 1108 to hold the arms (112 FIG. 1) down into the positions shown

The absorber 1110 (also 102 of FIG. 1) is an optical cavity and composed of three layers of nichrome/nitride/nichrome. To ensure the good adhesion of the absorber 1110 to the post 1112, a thin layer of silicon nitride was first deposited and the rest of absorber was then deposited. The nitride is deposited at 300° C. The photoresist can no longer be used as the absorber sacrificial layer. Silicon dioxide was used again as the sacrificial layer since it can be deposited relatively fast in PECVD (2 um/hour) and can be removed in the same way that the other sacrificial layer can be dissolved. After depositing the sacrificial oxide, the film should be patterned in ICP. To have sloped sidewalls, photoresist mask which is used for patterning should be hard baked to reflow and becomes tapered. After etching the post 1112 and before depositing the adhesive nitride layer for the absorber 1110, a quick clean was required to remove the polymers created during the oxide etching.

The absorber deposition comprises 5 steps. First a nitride layer was deposited in PECVD. Then, a thin layer of nichrome should be deposited followed by PECVD nitride again. The last step which is deposited at the top of nitride layer is nichrome deposition using sputtering technique. After this, another Parylene film may be deposited to protect the top films from exposure to HF vapor. However, if the nichrome is thick enough it would protect the underneath layers form HF. Then the absorber 1110 was patterned. The thickness of the photoresist should be carefully chosen since the absorber is composed of different layers and it takes time to etch all of them.

Nichrome can be wet or dry etched. Special photoresist with excellent adhesion to nichrome is required to mask the nichrome layer from its etchant (TFN). Otherwise, the photoresist will peel off or a large undercut occurs. Dry etching is also possible and can be done in chlorine based plasma. The selectivity of nichrome to photoresist in the developed recipe is 24 over 400 which is not good at all. In this work, 5 um thick resist is spun on the wafer and used as the mask.

There were four steps in the formation of the absorber 1110: etching the top nichrome, nitride, nichrome, and finally nitride. After this last step, photoresist can be removed and the devices can be released with either of wet or vapor phase etching techniques.

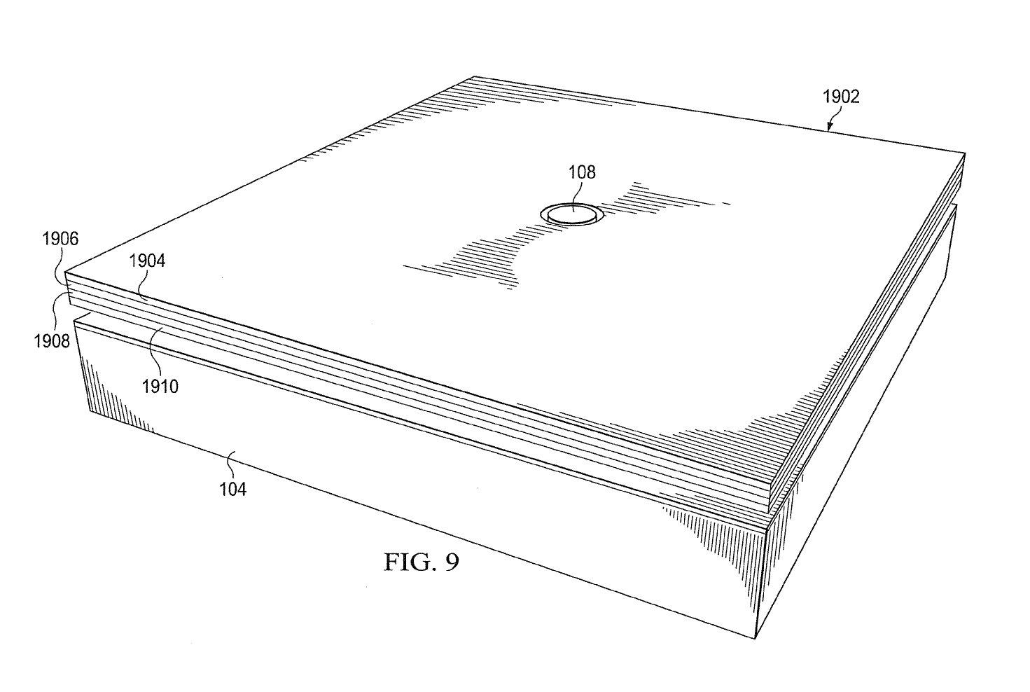

Referring now to FIG. 9 a perspective view of another embodiment of an IR detector according to aspects of the present disclosure is shown. This embodiment is similar to those previously described except as indicated. In the present embodiment, rather than an absorber platform 102 comprised of a monolayer of silicon nitride, a multilayer absorber platform 1902 is utilized. The absorber 1902 functions as an optical cavity. In one embodiment, a top metal layer 1904 overlays a dielectric layer 1906, which overlays a bottom metal layer 1908. Hence, the general structure is metal/dielectric/metal. In some embodiments the metal layers 1904, 1906 comprise nichrome and the dielectric layer 906 comprises silicon nitride.

In some embodiment, an adhesion layer 1910 may underlie all or a portion of the bottom metal layer 1908. The adhesion layer 1910 may comprise a thin layer of silicon nitride. The adhesion layer 1910 may be utilized to enhance adhesion of the platform 902 to the underlying structure to which it is attached.

FIG. 10 is a perspective view of the IR detector of FIG. 9 with the absorber 1902 removed for purposes of illustration. Here it can be seen that in the present embodiment, no membrane 106 (e.g., FIG. 1) interposes the post 108 and turning arms 112. In other words, the absorber post 108 attaches directly to the arms 112 containing the thermocouple wires 110. The removal of material contained in the membrane 106 reduces thermal mass of the hot junction and improves the time constant of the device 1900.

It will also be appreciated that to maximize sensitivity of the device 1900, thermal resistance between hot and cold junctions should be maximized. Parylene, having a low thermal conductivity, may be used to fabricate various structures of the device 1900, such as the turning arms 112. As described above, following deposition of Parylene, other fabrication steps may be performed. Thus, in some embodiments, Parylene-N may be advantageous over Parylene-C due to its higher melting point. The Parylene polymer may be deposited and then pattern using oxygen based plasma. Following patterning, oxygen plasma should be avoided through the rest of the fabrication. As described above, with respect to FIG. 8(c), removal of sacrificial layers the arms 112 may deform due to internal stresses. This may cause electrical discontinuities in the thermocouples. To avoid this deformation, one or more tethers 1912 (also comprising Parylene, or Parylene-N) may be added to the structure 1900. These may be formed during the fabrication process as a part of the structure comprising the arms 112.

Thus, the present invention is well adapted to carry out the objectives and attain the ends and advantages mentioned above as well as those inherent therein. While presently preferred embodiments have been described for purposes of this disclosure, numerous changes and modifications will be apparent to those of ordinary skill in the art. Such changes and modifications are encompassed within the spirit of this invention as defined by the claims.

### REFERENCES

1. P. W. Kruse, M. D. Blue, J. H. Garfunkel, W. D. Saur, “Long wavelength photo effects in mercury selenide, mercury telluride and mercury telluride-cadmium telluride,” Infrared Physics 2 (1962) 53-60
2. A. Rogalski, J. Piotrowski, “Intrinsic infrared detectors,” Progress in Quantum Electronics 12 (1988) 87-289.
3. B. F. Levine, “Quantum-well infrared photodetectors,” Journal of Applied Physics 74 (1993) R1-R81
4. R. A. Wood, N. A. Foss, “Micromachined bolometer arrays achieve low-cost imaging,” Laser Focus World, June, 1993, pp. 101-106
5. C. M. Hanson, Hybridpyroelectric-ferroelectric bolometer arrays, in: P. W. Kruse, D. D. Skatrud (Eds.), Semiconductors and Semimetals, Vol. 47, Academic Press, San Diego, 1997, pp. 123-174
6. T. Kanno, M. Saga, S. Matsumoto, M. Uchida, N. Tsukamoto, A. Tanaka, S. Itoh, A. Nakazato, T. Endoh, S. Tohyama, Y. Yamamoto, S. Murashima, N. Fujimoto, N. Teranishi, “Uncooled infrared focal plane array having 128_{—}128 thermopile detector elements,” Proceedings of SPIE 2269 (1994) 450-459T.
7. H. Jerominek, T. D. Pope, M. Renaud, N. R. Swart, F. Picard, M. Lehoux, S. Savard, G. Bilodeau, D. Audet, L. N. Phong, C. N. Qiu, “64×64, 128×128 and 240×_{—}320 pixel uncooled IR bolometric detector arrays,” Proceedings of SPIE 3061 (1997) 236-247
8. P. W. Kruse, Uncooled Thermal Imaging Arrays: Systems, and Applications, SPIE Press, Bellingham, 2001.
9. H. Beratan, C. Hanson, E. G. Meissner, “Low cost uncooled ferroelectric detector,” Proceedings of SPIE 2274 (1994) 147-156
10. P. W. Kruse, “Uncooled IR focal plane arrays,” Opto-Electronics Review 7 (1999) 253-258
11. D. Murphy, M. Ray, R. Wyles, J. Asbrock, N. Lum, A. Kennedy, J. Wyles, C. Hewitt, G. Graham, W. Radford, J. Anderson, D. Bradley, R. Chin, T. Kostrzewa, “High sensitivity (25 mm pitch) microbolometer FPAs and application development,” Proceedings of SPIE 4369 (2001) 222-234
12. J. Anderson, D. Bradley, D. C. Chen, R. Chin, K. Jurgelewicz, W. Radford, A. Kennedy, D. Murphy, M. Ray, R. Wyles, J. Brown, G. Newsome, “Low cost microsensors program,” Proceedings of SPIE 4369 (2001) 559-565.
13. C. M. Hanson, “Uncooled thermal imaging at Texas Instruments,” Proceedings of SPIE 2020 (1993) 330-339
14. R. K. McEwen, P. A. Manning, “European uncooled thermal imaging sensors,” Proceedings of SPIE 3698 (1999) 322-337
15. D. Murphy, M. Ray, A. Kennedy, J. Wyles, C. Hewitt, R. Wyles, E. Gordon, T. Sessler, S. Baur, D. Van Lue, S. Anderson, R. Chin, H. Gonzalez, C. Le Pere, S. Ton, and T. Kostrzewa, “Expanded applications for high performance VOx microbolometer FPAs,” Proc. SPIE, Vol. 5783, 448 (2005);
16. A. D. Oliver, W. G. Baer, K. D. Wise, A bulk-micromachined 1024-element uncooled infrared imager, Proceedings of 8th International Conference on Solid-State Sensors and Actuators (Transducers '95), and Eurosenso rs vol. IX, 1995, pp. 636-639
17. Masaki Hirota, Yasushi Nakajima, Masanori Saito, Fuminori Satou, and Makato Uchiyama, “120×90 element thermopile array fabricated with CMOS technology,” Proc. SPIE, Vol. 4820, 239 (2003);
18. Schaufelbuchl, A.; Munich, U.; Menolfi, C.; Brand, 0.; Paul, 0.; Huang, Q.; Baltes, H., “256-pixel CMOS-integrated thermoelectric infrared sensor array,” IEEE International Conference on Micro Electro Mechanical Systems MEMS 2001, pp. 200-203, 2001
19. M. C. Fote, S. Gaalema, “Progress towards high-performance thermopile imaging arrays,” Proceedings of SPIE 4369 (2001) 350-354
20. Marc C. Foote, T. R. Krueger, J. T. Schofield, Daniel J. McCleese, T. A. McCann, Eric W. Jones, and M. R. Dickie, “Space science applications of thermopile detector arrays,” Proc. SPIE, Vol. 4999, 443 (2003);
21. Ioffe, A. F., 1956, Poluprovoduikovye Termoelementy, Moskow-Leningrad.
22. L. D. Hicks, M. S. Dresselhaus, Phys. Rev. B 47, 12727-12731 (1993)
23. J.-P. Fleurial, A. Borschevsky, T. Caillat, D. T. Morelli, and G. P. Meisner, in Proc. 16th Int. Conf. Thermoelectrics (IEEE, Piscataway, N.J., 1997) p. 91.
24. T. Caillat, J.-P. Fleurial, and A. Borschevsky, J. Phys. Chem. Solids 58 (1997) p. 1119.
25. Q. Shen, L. Chen, T. Goto, T. Hirai, J. Yang, G. P. Meisner, and C. Uher, Appl. Phys. Lett. 79 (2001) p. 4165.
26. R. Venkatasubramanian, E. Siivola, T. Colpitts, and B. O'Quinn, Nature 413 (2001) p. 597.
27. D. Vashaee, A. Shakouri, J. Appl. Phys. 101, 053719 (2007).
28. D. Vashaee, A. Shakouri. Physical Review Letter, Vol. 92, no. 10, March 2004, pp. 106103-1.
29. G. S. Nolas, G. A. Slack, D. T. Modeli, T. M Tritt, and A. C. Ehrlich, J. Appl. Phys. 79, 4002 (1996)
30. J. P. Fluerial, T. Caillat, and A. Borshchevsky, in proceedings of the 13th international conference on thermoelectrics, pp. 40 (1994)
31. G. Chen, Phys. Rev. B: Condens. Matter Mater. Sci. 57, 14958 (1998)
32. R. Venkatasubramanian, E. Siivola, T. Colpitte, and B. O'Quinn, Nature 413, 596 (2001)
33. D. Vashaee, Y. Zhang, A. Shakouri, G. Zeng and Y. Chiu, Physical Review B 74, 195315 (2006)
34. D. Vashaee, A. Shakouri. Journal of Applied Physics, vol. 95, no. 3, pp. 1233-45 (2004)
35. T. C. Harman, P. J. Taylor, M. P. Walsh, and B. E. LaForge, Science 297, 2229 (2002)
36. K. F. Hsu, S. Loo, F. Guo, W. Chen, J. S. Dyck, C. Uher, T. Hogan, E. K. Polychroniadis, and M. G. Kanadtzidis, Science 303, 818 (2004)
37. B. Poudel, Q. Hao, Y. Ma, Y. Lan, A. Minnich, B. Yu, X. Yan, D. Wang, A. Muto, D. Vashaee, X. Chen, J. Liu, M. S. Dresselhaus, G. Chen, Z. Ren, Science, Vol. 320. no. 5876, pp. 634-638 (2008)
38. Allon I. Hochbaum, Renkun Chen, Raul Diaz Delgado, Wenjie Liang, Erik C. Garnett, Mark Najarian, Arun Majumdar & Peidong Yang, Nature 451, 163-167 (10 Jan. 2008).
39. T. Harman, “Quantum Dot Superlattice Thermoelectric Unicouples for Conversion of Waste Heat to Electrical Power” presented at the 2003 MRS Fall Meeting (Boston, Mass., Dec. 1-5, 2003).
40. Chi-Yuan Shih, Yang Chen, Yu-Chong Tai, Parylene-strengthened thermal isolation technology for microfluidic system-on-chip applications, Sensors and Actuators A: Physical, Volume 126, Issue 1, 26 Jan. 2006, pp. 270-276
41. M. Hirota, Y. Nakajima, M. Saito and M. Uchiyama, Sensors and Actuators A 135 (2007) 146-151
42. Foote, M. C., Gaalema, S., 16 Apr. 2001, SPIE Aerosense, Orlando, Fla., USA
43. D. Vashaee, C. LaBounty, X. Fang, G. Zeng, P. Abraham, J. E. Bowers, A. Shakouri, Proceedings of the SPIE—The International Society for Optical Engineering, vol. 4284, 2001. p. 139-44
44. Daryoosh Vashaee, Ali Shakouri, Microscale Thermophysical Engineering, Volume 8, No 2:91-100, 2004.
45. J. Kedzierski, J. Bokor, C. Kisielowski, “Fabrication of planar silicon. nanowires on silicon-on-insulator using stress limited oxidation,” Journal of Vacuum Science & Technology B (Microelectronics and Nanometer Structures), November-December 1997, vol. 15, no. 6, pp. 2825-8
46. S. Y Chen, J G Bomer, W G van der Wiel, et al., “Top-down fabrication of Sub-30 nm monocrystalline silicon nanowires using conventional microfabrication,” ACS NANO, Vol. 3, Issue 11, pp. 3485-3492, NOV 2009
47. K. R. Williams, K. Gupta, M. Wasilik, “Etch rates for micromachining processing-Part II,”, Journal of Microelectromechanical Systems, Vol. 12, no. 6, pp. 761-778, December 2003

1. A thermoelectric infrared detector comprising:
a platform forming an optical cavity and comprising a material that increases in temperature in response to incident infrared radiation, the platform covering substantially an entire area of the detector; and
a thermocouple attached directly to the platform and substantially suspended from contact with a substrate by at least one arm connected to the substrate.

2. The detector of claim 1 wherein the thermocouple comprises a thermoelectric connection embedded in the at least one arm.

3. The detector of claim 1, wherein the absorption platform connects directly to the at least one arm forming the thermocouple.

4. The detector of claim 1, wherein the absorption platform comprises at least one layer dielectric layer with at least two adjacent metal layers.

5. The detector of claim 4, wherein the at least two adjacent layers are on opposite sides of the dielectric layer.

6. The detector of claim 5, wherein the metal layers comprise nichrome.

7. The detector of claim 4, further comprising an adhesion layer underlying the dielectric layer and the two metal layers.

8. The detector of claim 1, wherein the at least one arm comprises Parylene-N.

9. The detector of claim 8, wherein the at least one arm is tethered to the substrate by at least one tether.

10. The detector of claim 9, wherein the tether comprises Parylene-N.

11. An infrared detector comprising:
a plurality of support arms proceeding from a substrate and containing a plurality of thermoelectric connections therein; and
an infrared absorber platform in thermal connection with the plurality of arms and heating the arms in response to absorbing infrared radiation;
wherein the thermoelectric connections form a thermocouple with the absorber, the absorber acting as a hot junction and the substrate acting as a cold junction, the thermocouple providing a voltage signal on the thermoelectric connections in proportion to the temperature difference between the hot and cold junctions.

12. The detector of claim 11, wherein the plurality of support arms comprise Parylene-N.

13. The detector of claim 11, further comprising at least one tether tethering at least one of the plurality of support arms to the substrate at a location other than where such support arm joins the substrate.

14. The detector of claim 11, wherein the absorber platform covers substantially an entire area of the detector.

15. The detector of claim 11, further comprising a silicon nitride post interposing the infrared absorber and the plurality of arms.

16. The detector of claim 11, wherein the absorber platform comprises a silicon nitride layer with a first nichrome layer on a first side of the silicon nitride layer and a second nichrome layer on a second side of the silicon nitride layer.

17. The detector of claim 16, further comprising an adhesion layer on a lower side of the absorber platform.

18. A method comprising:
providing an infrared absorber;
providing a plurality of Parylene-N support arms supporting the absorber away from the substrate;
attaching a thermally conductive connection from the substrate to the infrared absorber to detect heating of the absorber relative to the substrate.

19. The method of claim 18, further comprising forming the infrared absorber from a dielectric layer covered on two sides by metal layers.

20. The method of claim 18, wherein the infrared absorber covers substantially all of the support arms.
